(19) United States
(12) Patent Application Publication
(10) Pub. No.: US 2024/0324109 A1
(43) Pub. Date: Sep. 26, 2024

(54) SOLDER BARRIER CONTACT FOR AN INTEGRATED CIRCUIT

(71) Applicant: Western Digital Technologies, Inc., San Jose, CA (US)

(72) Inventors: Uthayarajan A/L Rasalingam, Penang (MY); Hudzaifah Yousof Bin Humayun, Pulau Pinang (MY); Babu Krishnamoorthy, Pulau Pinang (MY)

(21) Appl. No.: 18/357,379

(22) Filed: Jul. 24, 2023

Related U.S. Application Data
(60) Provisional application No. 63/491,186, filed on Mar. 20, 2023.

(51) Int. Cl. H05K 3/34; H05K 1/18

(52) U.S. Cl. CPC H05K 3/3436; H05K 1/181; H05K 2201/09136; H05K 2201/10734; H05K 2203/041; H05K 2203/0557

(57) ABSTRACT

A grid of connection points or surface mount features electrically and/or communicatively couples a first computing component to a second computing component. The grid of connection points include a first connection point type having a first structure and a second connection point type having a second structure. In an example, the first connection point type is a solder ball that is associated with a single signal pin and the second connection point type is a solder bar that is associated with multiple signal pins. One or more of the second connection point types are positioned at and/or around a perimeter of the first computing component, which reduces strain, stress and/or other mechanical forces on the first connection point types and/or on the first computing component and/or the second computing component.

### CROSS-REFERENCE TO RELATED APPLICATIONS

The present application claims priority to U.S. Provisional Application No. 63/491,186 entitled “SOLDER BARRIER CONTACT FOR AN INTEGRATED CIRCUIT”, filed Mar. 20, 2023, the entire disclosure of which is hereby incorporated by reference in its entirety.

### BACKGROUND

A ball grid array (BGA) is a type of surface mount packaging that is used to attach an integrated circuit to a printed circuit board. Typically, the BGA includes a number of solder balls arranged in a grid. The solder balls are used to make electrical connections between the integrated circuit and the printed circuit board.

However, when an integrated circuit is mounted to the printed circuit board using a BGA, the integrated circuit, solder balls and/or the printed circuit board are often subjected to various mechanical forces. These mechanical forces can cause the solder balls to crack or break. Additionally, the mechanical forces may cause the integrated circuit and/or the printed circuit board to warp. Warpage and cracked or broken solder balls cause signal integrity issues and reduce the overall reliability of the integrated circuit.

In order to combat the above, an underfill material is typically used to fill in space between the integrated circuit and the printed circuit board. The underfill material helps prevent warpage and also strengthens or otherwise improves the strength of the solder joints between the integrated circuit and the printed circuit board. However, underfill material increases manufacturing time and cost.

Accordingly, it would be beneficial to have surface mount connection features that address and/or reduce mechanical forces exerted on an integrated circuit and/or a printed circuit board. Additionally, it would be beneficial if the surface mount connection features reduce or eliminate the need for an underfill material.

### SUMMARY

The present application describes a grid of connection points or surface mount connection features for electrically and/or communicatively coupling a first computing component to a second computing component. In an example, the grid of connection points is or otherwise resembles a ball grid array (BGA) or a BGA package. However, unlike traditional ball grid arrays, the grid of connection points described herein consists of a first connection point type having a first structure and a second connection point type having a second structure.

In an example the first connection point type is a solder ball that is associated with a single signal pin and the second connection point type is a solder bar or solder barrier that is associated with multiple signal pins. The signal pins that are associated with the second connection point type may include a ground pin, a no-connect pin, and/or a non-critical pin.

Additionally, one or more of the second connection point types, and associated signal pins, are positioned at and/or around a perimeter of the first computing component. Positioning second connection point types at and/or around the perimeter of the first computing component reduces strain, stress and/or other mechanical forces on the first connection point types—especially those that are positioned within the perimeter of the first computing component—when the first computing component is communicatively and/or electrically coupled to the second computing component. The arrangement described above may also reduce strain and/or stress on the first computing component and/or on the second computing component.

Accordingly, examples of the present application describe an integrated circuit having various surface mount connection features. For example, the integrated circuit includes a substrate and a grid of connection points disposed on a surface of the substrate. In this example, the grid of connection points includes a first connection point type having a first structure. The first connection point type is associated with a single signal pin. The grid of connection points also includes a second connection point type. The second connection point type has a second structure that is different from the first structure. Additionally, the second connection point type is associated with multiple signal pins. The second connection point type is disposed on a perimeter of the substrate.

In another example, an integrated circuit includes a substrate and a grid of connection points disposed on a surface of the substrate. The grid of connection points includes a plurality of solder bars disposed around a perimeter of the substrate and a first plurality of solder balls disposed around the perimeter of the substrate. In an example, at least one solder ball of the plurality of solder balls is disposed between a first solder bar of the plurality of solder bars and a second solder bar of the plurality of solder balls. A second plurality of solder balls is disposed within the perimeter of the substrate.

In yet another example, a grid of connection points is described. The grid of connection points electrically and/or communicatively couples a first computing component to a second computing component. In this example, the grid of connection points includes a first connection means having a first structure. The first connection means is associated with a single signal means. The grid of connection points also includes a second connection means having a second structure that is different from the first structure. In an example, the second connection means is associated with multiple signal means. Additionally, the second connection means is disposed on a perimeter of the first computing component.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a conventional ball grid array (BGA) package according to an example.

FIG. 1B illustrates an example arrangement of signal pins associated with the conventional ball grid array package shown and described with respect to FIG. 1A.

FIG. 2 illustrates a connection point package having grid of connection points arranged on a substrate according to an example.

FIG. 3A illustrates a connection point package having a first connection point type and a second connection point type according to an example.

FIG. 3B illustrates a cross-section view of the connection point package shown and described with respect to FIG. 3A according to an example.

FIG. 4 illustrates how a grid of connection points is used to couple a first computing component to a second computing component according to an example.

FIG. 5 illustrates a printed circuit board having various pads that electrically and/or communicatively couple the printed circuit board to a computing component according to an example.

FIG. 6A illustrates an integrated circuit being coupled to a printed circuit board using a grid of connection points according to an example.

FIG. 6B illustrates an integrated circuit being coupled to a printed circuit board using a grid of connection points according to another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Examples described herein are directed to a grid of connection points or various surface mount connection features for electrically and/or communicatively coupling a first computing component to a second computing component. In an example, the first computing component may be an integrated circuit, a semiconductor chip or die, a flip chip die or other such computing component that is mounted to a second computing component. In an example, the second computing component may be a printed circuit board, a substrate, another integrated circuit, a BGA package and the like. In another example, the first computing component and/or the second computing component may be any computing component that is communicatively and/or electrically coupled to another computing component using a surface mounting technique (e.g., SMD, NSMD).

In an example, the grid of connection points or surface mount connection features is, or otherwise resembles, a ball grid array (BGA). However, unlike traditional ball grid arrays, the grid of connection points described herein consists of a first connection point type or a first surface mount connection feature having a first structure. Additionally, the grid of connection points includes a second connection point type or a second surface mount connection feature having a second structure.

In an example, the first connection point type is a solder ball that is associated with a single signal pin and the second connection point type is a solder bar or solder barrier that is associated with multiple signal pins. The signal pins that are associated with the first connection point type may include, but are not limited to, a power pin, a data pin, a control pin, a clock pin, a ground pin, a no-connect pin, and/or a non-critical pin. The signal pins that are associated with the second connection point type may include a ground pin, a no-connect pin, and/or a non-critical pin.

Additionally, one or more of the second connection point types, and associated signal pins, are positioned at and/or around a perimeter of the first computing component. Positioning second connection point types at and/or around the perimeter of the first computing component reduces strain, stress and/or other mechanical forces on the first connection point types—especially those that are positioned within the perimeter of the first computing component. This arrangement may also reduce strain and/or stress on the first computing component and/or on the second computing component when the computing components are communicatively and/or electrically coupled. The number and/or length of each second connection point type at and/or around the perimeter of the first computing component may be based on one or more factors, including, but not limited to, the size/dimensions of the first computing component and/or a determined or desired bond strength requirement.

In an example, the first connection point type(s) and the second connection point type(s) that are positioned at or around the perimeter of the first computing component may form a barrier (e.g., a solder barrier). The barrier may be used in place or in lieu of a underfill or other material that typically encapsulates a bottom side of an integrated circuit.

Accordingly, the present application provides many technical benefits including, but not limited to, reducing manufacturing cost and time of integrated circuits, semiconductor chips and/or packages by removing or reducing a need for underfill, reducing an amount of stress on connection points and/or on the computing components themselves, increasing a bond strength between bonded computing components and enabling semiconductor manufacturers to customize a bond strength between computing components based on various needs.

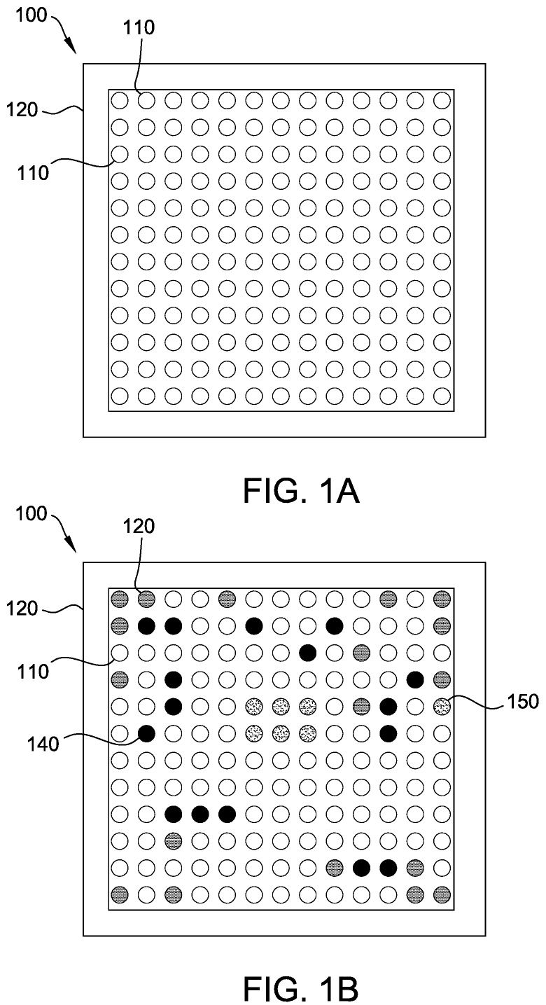

These and other examples will be shown and described in greater detail with respect to FIG. 1-FIG. 6B.

FIG. 1A illustrates a conventional ball grid array package 100 according to an example. The ball grid array package 100 may be associated with, or otherwise be a part of, an integrated circuit or other electronic component. The ball grid array package 100 includes a number of individual solder balls 110 or bumps arranged on a substrate 120 of the integrated circuit. As shown in FIG. 1A, the solder balls 110 are typically arranged in a pattern or grid.

Each solder ball 110 is typically associated with a signal pin. Each signal pin may be of various types and may be responsible for carrying or otherwise providing different types of signals between the integrated circuit and a printed circuit board on which the ball grid array package 100 is coupled. For example, each solder ball 110 may be associated with a ground pin, a no-connect pin, a non-critical pin, a power pin, a data pin, a control pin or a clock pin. In conventional arrangements, some of the various types of signal pins are arranged at random locations within the grid and/or at one or more cover locations within the grid.

For example, and as shown in FIG. 1B, the ball grid array package 100 may include a solder ball 110 having or otherwise being associated with a first signal pin type (e.g., a data pin, a power pin, a control pin), a solder ball 130 having or otherwise being associated with a second pin type (e.g., a no-connect pin), a solder ball 140 having or otherwise being associated with a third pin type (e.g., a ground pin) and a solder ball 150 having or otherwise being associated with a fourth pin type (e.g., a non-critical pin or a dummy pin). As indicated above, the arrangement of some or all of the various solder balls and their associated signal pins may be random, semi-random, or dependent on a design of the BGA package 100 itself.

As indicated above, when the BGA package 100 is mounted to a printed circuit board, various mechanical forces are exerted on the BGA package 100 and on the printed circuit board. Some of these mechanical forces include bending, twisting, compression, tension and shearing. As a result, the BGA package 100 may be subjected to solder joint failures and/or warpage which may cause signal integrity issues and reduce the overall reliability of the BGA package 100.

In order to reduce the negative effects described above, the present application describes clustering approach in which signal pins of a certain types are placed on a perimeter of a substrate of an integrated circuit or surface mount package. The surface mount package includes different types of connection points or surface mount connection features that strengthen the connection between an integrated circuit and the printed circuit board. These surface mount connection features may also counteract the mechanical forces listed above.

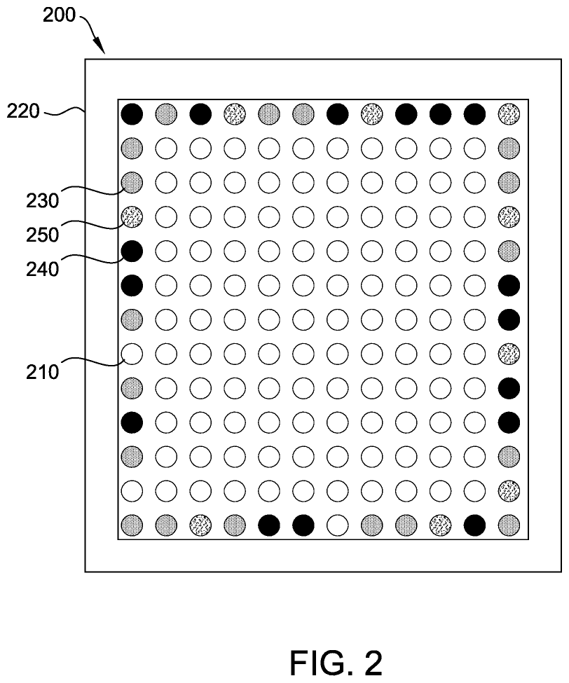

FIG. 2 illustrates a connection point package 200 having grid of connection points 210 arranged on a substrate 220 according to an example. The connection point package 200, along with the grid of connection points 210, may be part of or otherwise associated with an integrated circuit, a surface mount package, a semiconductor die, or various other computing components.

Each connection point 210 or surface mount feature may include or otherwise be associated with a signal pin. For example, the connection point package 200 may include a connection point 210 having or otherwise being associated with a first signal pin type (e.g., a data pin, a power pin, a control pin), a connection point 230 having or otherwise being associated with a second signal pin type (e.g., a no-connect pin), a connection point 240 having or otherwise being associated with a third signal pin type (e.g., a ground pin) and a connection point 250 having or otherwise being associated with a fourth signal pin type (e.g., a non-critical pin or a dummy pin).

Unlike the arrangement of signal pins shown in FIG. 1B, certain/specific signal pins of the connection point package 200 are placed or are otherwise disposed on an outer perimeter of the substrate 220. In examples described herein, signal pins that are placed or are otherwise disposed on the perimeter of the substrate 220 are referred to as “common signal pins” and may include no-connect pins, ground pins, non-critical pins, dummy pins. In an example, all or substantially all of the common signal pins of a given connection point package 200 should be placed at the perimeter of the substrate 220. In an example, additional common signal pins (e.g., dummy pins) may be added to the connection point package 200 to ensure that the entire perimeter of the substrate 220 of the connection point package 200 includes common signal pins. However, as shown in FIG. 2, it is contemplated that “non-common signal pins” (e.g., data pins, power pins, control pins) may also be placed or otherwise disposed at the perimeter of the substrate 220.

While non-common signal pins may be placed at the perimeter of the substrate 220, additional non-common signal pins are located within the perimeter of the substrate 220. Additionally, while FIG. 2 shows a particular pattern, number and type of connection points and associated signal pins, the connection point package 200 may have any number of connection points, common signal pins, non-common signal pins and patterns. In an example, the arrangement of the various common signal pins and/or the associated connection points, including any signal routing between various components (e.g., a semiconductor die), signal pins and/or connection points may be achieved during a fabrication process.

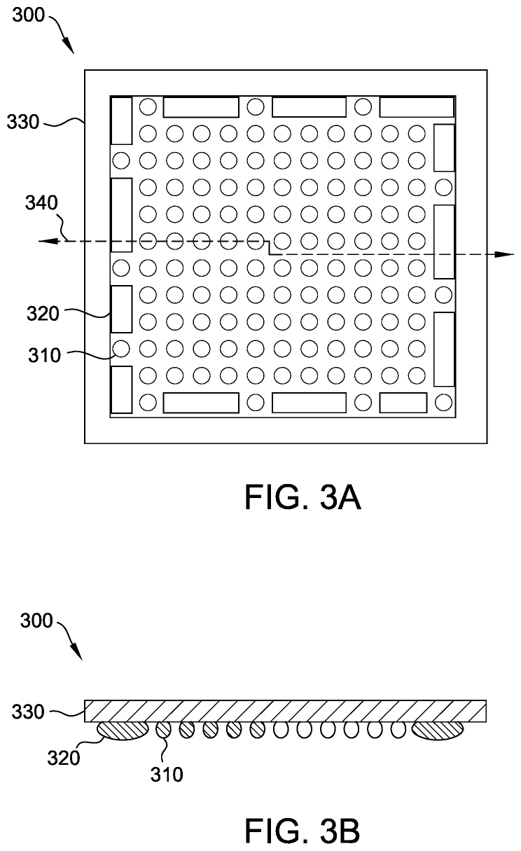

Once the signal pins have been arranged in the manner illustrated by FIG. 2, a first connection point type and a second connection point type may be added to the substrate 220. For example and referring to FIG. 3A, FIG. 3A illustrates a connection point package 300 having a first connection point type 310 and a second connection point type 320. Each of the first connection point type 310 and the second connection point type 320 are arranged on a substrate 330.

In an example, the first connection point type 310 is a solder ball. The first connection point type may be associated with a single signal pin. For example, the single signal pin may be a common signal pin (e.g., a no-connect pin, a ground pin, a non-critical pin, a dummy pin). In another example, the single signal pin is a non-common signal pin (e.g., a data pin, a power pin, a control pin).

As shown in FIG. 3, one or more first connection point types 310 may be disposed on a perimeter of the substrate 330. Likewise, one or more additional first connection point types 310 may be arranged or otherwise disposed within the perimeter of the substrate 330. The one or more additional first connection point types 310 may be arranged in a pattern or grid. The second connection point type 320 may be a solder bar, a flat or substantially flat solder pad, or another structure that may form a partial barrier (or a complete barrier) around the perimeter of the substrate 330.

Solder paste or another material may be used for each first connection point type 310 and for the second connection point type 320. In another example, material that is used for the second connection point type 320 may be different than the material that is used for the first connection point type 310. In another example, solder or other material that is used for each of the first connection point type 310 and/or the second connection point type 320 may be based on the type of signal pins associated with the first connection point type 310 and the second connection point type 320.

In an example, the second connection point type 320 is associated with multiple signal pins. For example, one connection point type 320 may be associated with two signal pins while another second connection point type 320 may be associated with three signal pins. Additionally, the second connection point type 320 may extend between a first location on the perimeter of the substrate 330 at which a first signal pin is located and a second location on the perimeter of the substrate 330 at which a second signal pin is located. Thus, the second connection point type 320 may have length and/or width dimensions that are greater than length and/or width dimensions of the first connection point type 310. Although the examples above describe the second connection point type 320 having two and three signal pins, a single second connection point type 320 may have or otherwise be associated with any number of signal pins.

In an example, the signal pins that are included or are otherwise associated with the second connection point type 320 are common signal pins (e.g., no-connect pins, ground pins, non-critical pins, dummy pins). The signal pins that are included or otherwise associated with the second connection point type 320 may be the same type of signal pins (e.g., two no-connect pins, three ground pins). In another example, the signal pins that are included or otherwise associated with the second connection point type 320 may be different types of signal pins (e.g., a no-connect pin and a ground pin).

As shown in FIG. 3A, one or more first connection point types 310 may be interleaved or otherwise placed in between two second connection point types 320. This configuration helps ensure that any heat that is generated by computing components of the connection point package 300 (or any heat from a reflow process or other manufacturing process) is not trapped within the perimeter of the substrate 330.

The arrangement of the first connection point type 310 and the second connection point type 320 around the perimeter of the substrate 330 helps reduce mechanical forces on the connection point package 300 and/or on a printed circuit board on which the connection point package 300 is placed. In an example, the arrangement of first connection point types 310 and second connection point types 320 may be based on various factors including, but not limited to, an intended use of the connection point package 300, various electrical and/or computing components contained or otherwise associated with the connection point package 300, a size of the connection point package 300, an amount of stress exhibited on/by the connection point package 300 and so on. In some examples, the second connection point type 320 may include electrical signals or otherwise include electrical signal pins. For example, the second connection point type 320 may include GND signals if NC pins are not available.

FIG. 3B illustrates a cross-section view of the connection point package 300 shown and described with respect to FIG. 3A according to an example. The cross-section view shown in FIG. 3B is taken along the bi-directional arrow 340 shown in FIG. 3A.

As shown in FIG. 3B, a height of each of the first connection point types 310 is equivalent or substantially equivalent to a height of each of the second connection point type 320. This helps ensure that the connection point package 300 may be correctly and completely coupled to a printed circuit board or other computing component.

In an example and in order to help ensure a height of each of the first connection point types 310 is equivalent or substantially equivalent to a height of each of the second connection point type 320, different amounts of solder paste and/or material may be used for each of the first connection point types 310 and each of the second connection point types 320.

In another example, a solder mask or other layer may be used to help ensure the height of each of the first connection point types 310 is equivalent or substantially equivalent to the height of each of the second connection point types 320. A solder mask may also be used to help ensure that the various first connection point types 310 and/or the various second connection point types 320 only contact corresponding pads on printed circuit board on which the connection point package 300 is mounted.

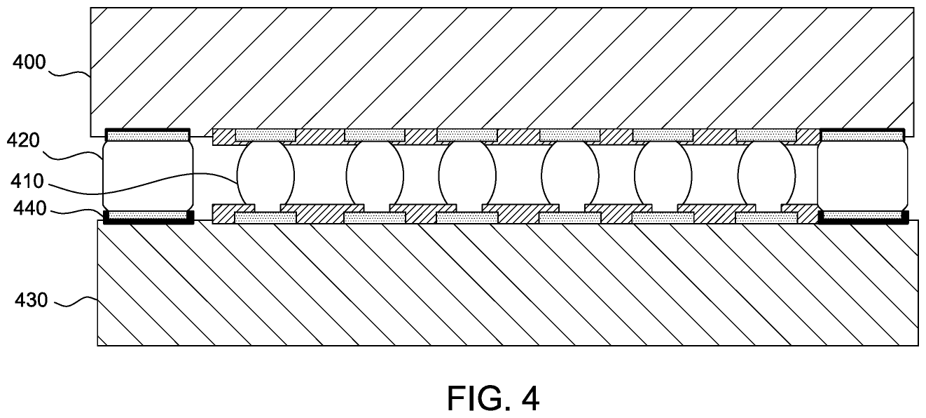

FIG. 4 illustrates how a grid of connection points is used to couple a first computing component 400 to a second computing component 430 according to an example. In an example, the first computing component 400 is an integrated circuit, a flip chip die, a flip chip device/package or other computing component and the second computing component 430 is a substrate, a printed circuit board or the like.

In an example, the first computing component 400 is similar to the connection point package 300 shown and described with respect to FIG. 3A. As such, the first computing component 400 includes a first connection point type 410 and a second connection point type 420. As shown in FIG. 4 and as previously described, the second connection point type 420 is disposed on a perimeter of the first computing component 400. The second connection point type 420 also has a larger area when compared to the first connection point type 410. As such, the second connection point type 420 may reduce the strain and/or stress on the first connection point types 410 that are provided within the perimeter.

In an example, the second connection point type 420 may reduce, absorb or counteract any mechanical forces that are exerted on/by the first computing component 400 and/or the second computing component 430. As such, an underfill material may not be needed to improve the mechanical strength of solder joints between the first computing component 400 and the second computing component 430. By removing a need for an underfill material, speed of fabrication may increase while costs associated with fabrication may decrease.

As also shown in FIG. 4, the second computing component 430 may include various pads 440. The pads 440 may be copper pads or land pads that may be used to communicatively and/or electrically couple the first computing component 400 to the second computing component 430. In an example, a shape, size and/or arrangement/pattern of the pads 440 may be similar to the shape, size, and/or arrangement/pattern of the first connection point type 410 and the second connection point type 420.

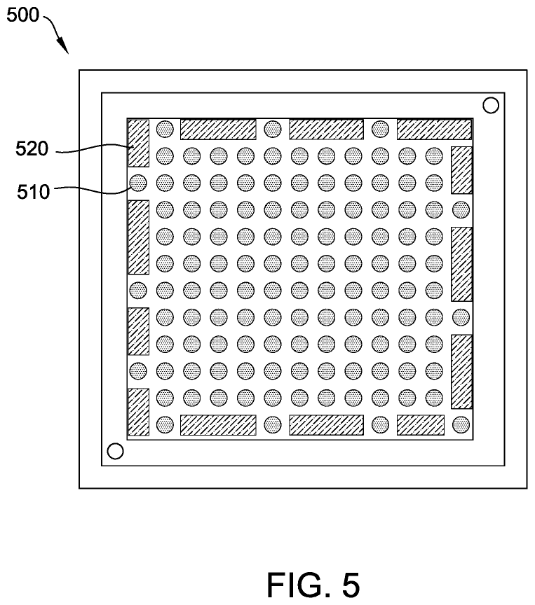

FIG. 5 illustrates a printed circuit board 500 having various pads that electrically and/or communicatively couple the printed circuit board 500 to a computing component according to an example. In an example, the printed circuit board 500 may be similar to the printed circuit board 430 shown and described with respect to FIG. 4.

As shown in FIG. 5, the printed circuit board 500 may include a first type of pad 510 and a second type of pad 520. The various pads may be made of copper or other material that may be used to electrically and/or communicatively couple the printed circuit board 500 to the computing component.

The first type of pad 510 may have a shape and/or size that conforms to, or substantially matches, a shape and/or size of one or more first connection point types (e.g., first connection point type 310 (FIG. 3A)) of a computing component (e.g., the first computing component 400 (FIG. 4)). Likewise, the second type of pad 520 may have a shape and/or size that conforms to, or substantially matches, a shape and/or size of one or more second connection point types (e.g., first connection point type 310 (FIG. 3A)) of the computing component.

Additionally, a patten or arrangement of the first type of pad 510 and the second type of pad 520 of the printed circuit board 500 may be the same or similar to a pattern and/or arrangement of various connection points on the computing component. For example, the pattern and/or the arrangement of the first connection point type 310 and the second connection point type 320 of the connection point package 300 shown and described with respect to FIG. 3A matches with the pattern/arrangement of the first type of pad 510 and the second type of pad 520 of the printed circuit board 500.

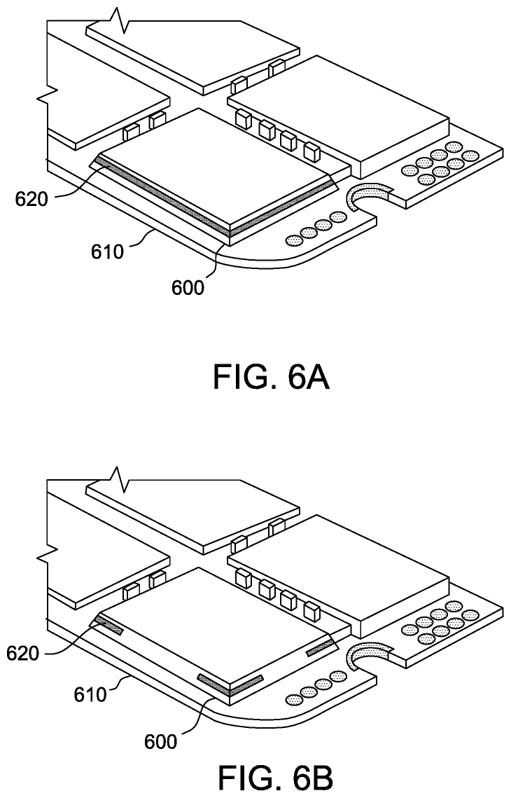

FIG. 6A illustrates an integrated circuit 600 being coupled to a printed circuit board 610 using a grid of connection points 620 according to an example. Likewise, FIG. 6B illustrates an integrated circuit 610 being coupled to a printed circuit board 610 using a grid of connection points 620 according to another example. In each example, the printed circuit board 610 may be similar to the printed circuit board 500 shown and described with respect to FIG. 5. Additionally, the integrated circuit 600 may be similar to the connection point package 300 shown and described with respect to FIG. 3A.

In the example shown in FIG. 6A, the grid of connection points 620 extends around or substantially around a perimeter of the integrated circuit 600. In the example shown in FIG. 6B, the grid of connection points 620 extends around the corners of the integrated circuit 610. Although specific examples are shown and described, the grid of connection points 620 may be arranged in any pattern. Additionally, and as described above, in each example, an underfill material is not needed or required to reduce strain and/or stress between the integrated circuit 600 and the printed circuit board 610 nor is an underfill needed to improve the mechanical strength of any joints/connections between integrated circuit 600 and the printed circuit board 610.

As set forth herein, examples of the present application describe an integrated circuit, comprising: a substrate; and a grid of connection points disposed on a surface of the substrate, the grid of connection points comprising: a first connection point type having a first structure and being associated with a single signal pin; and a second connection point type having a second structure that is different from the first structure and being associated with multiple signal pins, the second connection point type being disposed on a perimeter of the substrate. In an example, the first connection point type is a solder ball and the second connection point type is a solder bar. In an example, multiple second connection point types are disposed around the perimeter of the substrate and wherein at least one first connection point type is disposed around the perimeter between the multiple second connection point types. In an example, a height of the first connection point type is substantially equivalent to a height of the second connection point type. In an example, the single signal pin and the multiple signal pins are selected from a group comprising: a ground pin; a no-connect pin; and a non-critical pin. In an example, the single signal pin is selected from a group comprising: a power pin; a data pin; a control pin; and a clock pin. In an example, the integrated circuit is coupled to a printed circuit board and wherein the printed circuit board comprises copper pads that at least substantially match a shape and a layout of the first connection point type and a shape and a layout of the second connection point type disposed on the substrate.

Examples also describe an integrated circuit, comprising: a substrate; and a grid of connection points disposed on a surface of the substrate, the grid of connection points comprising: a plurality of solder bars disposed around a perimeter of the substrate; a first plurality of solder balls disposed around the perimeter of the substrate, wherein at least one solder ball of the plurality of solder balls is disposed between a first solder bar of the plurality of solder bars and a second solder bar of the plurality of solder balls; and a second plurality of solder balls disposed within the perimeter of the substrate. In an example, each of the plurality of solder bars are associated with at least two signal pins and wherein each solder ball of the first plurality of solder balls and each solder ball of the second plurality of solder balls are associated with a single signal pin. In an example, the single signal pin and the at least two signal pins are selected from a group comprising: a ground pin; a no-connect pin; and a non-critical pin. In an example, the single signal pin is selected from a group comprising: a power pin; a data pin; a control pin; and a clock pin. In an example, the integrated circuit is coupled to a printed circuit board and wherein the printed circuit board comprises copper pads that at least substantially match a shape and a layout of the first connection point type and a shape and a layout of the second connection point type disposed on the substrate. In an example, the integrated also includes a solder mask that causes a height of each of the plurality of solder bars to be substantially equivalent to a height of each of the first plurality of solder balls and to a height of each of the second plurality of solder balls.

Other examples describe a grid of connection points for electrically coupling a first computing component to a second computing component, comprising: a first connection means having a first structure and being associated with a single signal means; and a second connection means having a second structure that is different from the first structure and being associated with multiple signal means, the second connection means being disposed on a perimeter of the first computing component. In an example, the first connection means is a solder ball and the second connection means is a solder bar. In an example, multiple second connection means are disposed around the perimeter of the first computing component and wherein at least one first connection means is disposed around the perimeter of the first computing component between the multiple second connection means. In an example, the single signal means and the multiple signal means are selected from a group comprising: a ground signal means; a no-connect signal means; and a non-critical signal means. In an example, the single signal means is selected from a group comprising: a power signal means; a data signal means; a control signal means; and a clock signal means. In an example, the second computing component is a printed circuit board that comprises a third connection means having, the third connection means having one or more shapes and a layout that substantially match a shape and layout of the first connection means and a shape and a layout of the second connection means disposed on the first computing component. In an example, the grid of connection points also includes a masking means that causes a height of the first connection means to be substantially equivalent to a height of the second connection means.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An integrated circuit, comprising:
a substrate; and
a grid of connection points disposed on a surface of the substrate, the grid of connection points comprising:
a first connection point type having a first structure and being associated with a single signal pin; and
a second connection point type having a second structure that is different from the first structure and being associated with multiple signal pins, the second connection point type being disposed on a perimeter of the substrate.

2. The integrated circuit of claim 1, wherein the first connection point type is a solder ball and the second connection point type is a solder bar.

3. The integrated circuit of claim 1, wherein multiple second connection point types are disposed around the perimeter of the substrate and wherein at least one first connection point type is disposed around the perimeter between the multiple second connection point types.

4. The integrated circuit of claim 1, wherein a height of the first connection point type is substantially equivalent to a height of the second connection point type.

5. The integrated circuit of claim 1, wherein the single signal pin and the multiple signal pins are selected from a group comprising: a ground pin; a no-connect pin; and a non-critical pin.

6. The integrated circuit of claim 1, wherein the single signal pin is selected from a group comprising: a power pin; a data pin; a control pin; and a clock pin.

7. The integrated circuit of claim 1, wherein the integrated circuit is coupled to a printed circuit board and wherein the printed circuit board comprises copper pads that at least substantially match a shape and a layout of the first connection point type and a shape and a layout of the second connection point type disposed on the substrate.

8. An integrated circuit, comprising:
a substrate; and
a grid of connection points disposed on a surface of the substrate, the grid of connection points comprising:
a plurality of solder bars disposed around a perimeter of the substrate;
a first plurality of solder balls disposed around the perimeter of the substrate, wherein at least one solder ball of the plurality of solder balls is disposed between a first solder bar of the plurality of solder bars and a second solder bar of the plurality of solder balls; and
a second plurality of solder balls disposed within the perimeter of the substrate.

9. The integrated circuit of claim 8, wherein each of the plurality of solder bars are associated with at least two signal pins and wherein each solder ball of the first plurality of solder balls and each solder ball of the second plurality of solder balls are associated with a single signal pin.

10. The integrated circuit of claim 9, wherein the single signal pin and the at least two signal pins are selected from a group comprising: a ground pin; a no-connect pin; and a non-critical pin.

11. The integrated circuit of claim 9, wherein the single signal pin is selected from a group comprising: a power pin; a data pin; a control pin; and a clock pin.

12. The integrated circuit of claim 8, wherein the integrated circuit is coupled to a printed circuit board and wherein the printed circuit board comprises copper pads that at least substantially match a shape and a layout of the first connection point type and a shape and a layout of the second connection point type disposed on the substrate.

13. The integrated circuit of claim 8, further comprising a solder mask that causes a height of each of the plurality of solder bars to be substantially equivalent to a height of each of the first plurality of solder balls and to a height of each of the second plurality of solder balls.

14. A grid of connection points for electrically coupling a first computing component to a second computing component, comprising:
a first connection means having a first structure and being associated with a single signal means; and
a second connection means having a second structure that is different from the first structure and being associated with multiple signal means, the second connection means being disposed on a perimeter of the first computing component.

15. The grid of connection points of claim 14, wherein the first connection means is a solder ball and the second connection means is a solder bar.

16. The grid of connection points of claim 14, wherein multiple second connection means are disposed around the perimeter of the first computing component and wherein at least one first connection means is disposed around the perimeter of the first computing component between the multiple second connection means.

17. The grid of connection points of claim 14, wherein the single signal means and the multiple signal means are selected from a group comprising: a ground signal means; a no-connect signal means; and a non-critical signal means.

18. The grid of connection points of claim 14, wherein the single signal means is selected from a group comprising: a power signal means; a data signal means; a control signal means; and a clock signal means.

19. The grid of connection points of claim 14, wherein the second computing component is a printed circuit board that comprises a third connection means, the third connection means having one or more shapes and a layout that substantially match a shape and layout of the first connection means and a shape and a layout of the second connection means disposed on the first computing component.

20. The grid of connection points of claim 14, further comprising a masking means that causes a height of the first connection means to be substantially equivalent to a height of the second connection means.
